(19) United States
(12) Patent Application Publication
(10) Pub. No.: US 2019/0006328 A1
(43) Pub. Date: Jan. 3, 2019

(54) DISPLAY DEVICE

(71) Applicant: InnoLux Corporation, Miao-Li County (TW)

(72) Inventors: Yi-An CHEN, Miao-Li County (TW); Kuan-Hung KUO, Miao-Li County (TW); Tsau-Hua HSIEH, Miao-Li County (TW); Shu-Ming KUO, Miao-Li County (TW); Chih-Yung HSIEH, Miao-Li County (TW)

(21) Appl. No.: 15/996,696

(22) Filed: Jun. 4, 2018

Related U.S. Application Data
(60) Provisional application No. 62/527,198, filed on Jun. 30, 2017.

(30) Foreign Application Priority Data
Dec. 26, 2017 (CN) 201711435140.1

(51) Int. Cl. H01L 25/075; H01L 27/12; H01L 33/50; H01L 33/58; H01L 33/62; G02B 1/11; G02B 5/30

(52) U.S. Cl. CPC H01L 25/0753; H01L 27/1214; H01L 33/507; H01L 2933/0083; H01L 33/62; G02B 1/11; G02B 5/3025; H01L 33/58

(57) ABSTRACT

A display device is provided. The display device includes a first substrate, a first light-emitting element, a second substrate, a light conversion layer and a light filter layer. The first light-emitting element is disposed on the first substrate. The second substrate is opposite to the first substrate. The light conversion layer is disposed on the second substrate and corresponds to the first light-emitting element. The light filter layer is disposed on the second substrate, wherein the transmittance of the light filter layer is lower than or equal to 1% for light with a wavelength shorter than 430 nm.

### CROSS REFERENCE TO RELATED APPLICATIONS

This application claims the benefit of U.S. Provisional Application No. 62/527,198, filed Jun. 30, 2017, and claims priority of China Patent Application No. 201711435140.1, filed Dec. 26, 2017, the entirety of which are incorporated by reference herein.

### BACKGROUND

### Technical Field

The disclosure relates to display devices, and in particular to a display device with a short-wavelength light filter layer.

### Description of the Related Art

In display devices that use a quantum-dots technique, narrow waveform color light can be obtained by using short-wavelength (such as blue light) light-emitting diodes (LEDs) and converting the light color through a quantum dot material. Therefore, the color saturation of the display device can be enhanced.

However, if the converting efficiency of the quantum dot material needs to be enhanced, shorter wavelength LEDs must be used. Using shorter wavelength LEDs may cause the display device to not conform to a specific color gamut standard (such as sRGB, DCI-P3, or Adobe RGB). In addition, ambient light, which is incident from outside the display device, may cause the LEDs or quantum dot materials to reflect or excite unnecessary light. Therefore, the contrast of the display device is decreased.

### BRIEF SUMMARY

Some embodiments of the disclosure provide a display device, including a first substrate, a first light-emitting element, a second substrate, a light conversion layer and a light filter layer. The first light-emitting element is disposed on the first substrate. The second substrate is opposite to the first substrate. The light conversion layer is disposed on the second substrate and corresponds to the first light-emitting element. The light filter layer is disposed on the second substrate, wherein the transmittance of the light filter layer is lower than or equal to 1% for light with a wavelength shorter than 430 nm.

To clarify the features and advantages of the present disclosure, a detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 shows an absorption spectrum and an emission spectrum of a green quantum dot material.

FIG. 2 is a cross-sectional view of a display device in accordance with an embodiment of the present disclosure.

FIG. 3A shows an absorption spectrum of a red quantum dot material and a transmission spectrum of a red photoresist.

FIG. 3B shows an absorption spectrum of a green quantum dot material and a transmission spectrum of a green photoresist.

FIG. 3C shows an absorption spectrum of a blue quantum dot material and a transmission spectrum of a blue photoresist.

FIG. 4 is a cross-sectional view of the display device in accordance with another embodiment of the present disclosure.

FIG. 5 is a cross-sectional view of the display device in accordance with another embodiment of the present disclosure.

FIG. 6 is a cross-sectional view of the display device in accordance with another embodiment of the present disclosure.

FIG. 7 is a cross-sectional view of the display device in accordance with another embodiment of the present disclosure.

FIG. 8 is a cross-sectional view of the display device in accordance with another embodiment of the present disclosure.

FIG. 9 is a cross-sectional view of the display device in accordance with another embodiment of the present disclosure.

FIG. 10A is an emission spectrum of a light conversion layer in accordance with an embodiment of the present disclosure.

FIG. 10B is an emission spectrum of the light conversion layer in accordance with another embodiment of the present disclosure.

### DETAILED DESCRIPTION

The display devices in some embodiments of the present disclosure are described in detail in the following description. It should be appreciated that the following detailed description provides various embodiments and examples in order to perform various patterns of the present disclosure. The specific elements and configurations described in the following detailed description are set forth in order to clearly describe the present disclosure. It will be apparent that the exemplary embodiments set forth herein are used merely for the purpose of illustration, and the inventive concept may be embodied in various forms without being limited to those exemplary embodiments. In addition, the drawings of different embodiments may use repeated numerals or marks. Those repetitions are used merely in order to clearly describe the present disclosure. However, the use of repeated numerals in the drawings of different embodiments does not suggest any correlation between different embodiments and/or configurations. In addition, in this specification, expressions such as “first material layer disposed on/over/above a second material layer”, may indicate the direct contact of the first material layer and the second material layer, or it may indicate a non-contact state with one or more intermediate layers between the first material layer and the second material layer. In the above situation, the first material layer may not be in direct contact with the second material layer.

It should be understood that elements or devices in the figures may exist in various forms which are known to those skilled in the art. In addition, when a certain layer is “on” another layer or the substrate, it may indicate the certain layer is “directly” on the other layer or the substrate, or the certain layer is over the other layer or the substrate, or another layer is disposed between the other layer and the substrate.

In addition, in this specification, relative expressions may be used. For example, “lower”, “bottom”, “higher” or “top” are used to describe the position of one element relative to another. It should be appreciated that if a device is flipped upside down, an element that is “lower” will become an element that is “higher”.

The terms “about”, “substantially” and “approximately” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. When there is no specific description, the stated value includes the meaning of “about”, “substantially”, or “approximately”.

It should be understood that, although the terms “first”, “second”, “third” etc. may be used herein to describe various elements, components, regions, layers and/or portions, and these elements, components, regions, layers and/or portions should not be limited by these terms. These terms are merely used to distinguish one element, component, region, layer, and/or portion. Thus, a first element, component, region, layer and/or portion discussed below could be termed a second element, component, region, layer or portion without departing from the teachings of the present disclosure.

Unless defined otherwise, all the terms (including technical and scientific terms) used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined in the present disclosure.

This description of the exemplary embodiments is intended to be read in connection with the accompanying drawings, which are to be considered part of the entire written description. It should be appreciated that the drawings are not drawn to scale. The shape and the thickness of embodiments may be exaggerated in the drawings to clarify the features of the present disclosure. In addition, structures and devices are shown schematically in order to clarify the features of the present disclosure.

In some embodiments of the present disclosure, relative terms such as “downwards,” “upwards,” “horizontal,” “vertical,”, “below,” “above,” “top” and “bottom” as well as derivative thereof should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are in contact with one another either directly or indirectly, wherein there are other structures disposed between both the structures, unless expressly described otherwise. These relative terms also include the relationships wherein both structures are movable or rigid attachments.

It should be noted that, the term “substrate” is meant to include elements formed on a glass substrate and various layers overlying the glass. All semiconductor element needed may be already formed on the glass substrate. However, the glass substrate is represented with a flat substrate in order to simplify the drawing. In addition, the term “substrate surface” is meant to include the uppermost exposed layers on a glass substrate, such as an insulating layer and/or metallic lines.

The embodiments of the present disclosure provides a display device with a short-wavelength light filter layer, and thereby in the case where the conversion efficiency of the quantum dot material is enhanced, the display device still conforms to a specific color gamut standard. Also, the external ambient light is prevented from being reflected or excited as an unnecessary light so that the contrast is decreased.

The disclosure may be used in electronic device, for example a display device, sensing device. And the electronic may be a tiled electric device. The display device may be a tiled display, OLED display, LED display, Flexible display.

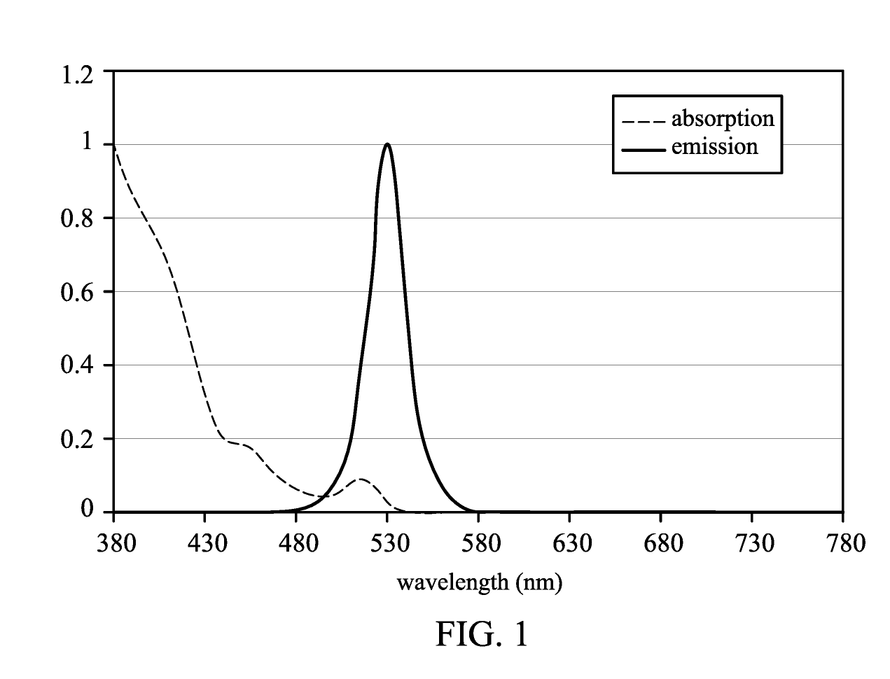

In general, no matter which the color semiconductor quantum dot material is, the color semiconductor quantum dot material has great absorption intensity for light with a wavelength shorter than 430 nm. Therefore, if using the semiconductor quantum dot material and a light source in which the peak wavelength is shorter than 430 nm, the light conversion efficiency of the quantum dot material can be enhanced. A green quantum dot material is described as an example in the following. FIG. 1 shows an absorption spectrum and an emission spectrum of a green quantum dot material. As shown in FIG. 1, the horizontal axis represents wavelength, in which the unit is nanometer (nm). The vertical axis represents a normalized relative intensity, therefore there is no unit. The dotted line is the absorption spectrum of the green quantum dot material, and the solid line is the emission spectrum of the same. The green quantum dot material has great absorption intensity for light with a wavelength shorter than 430 nm (as shown in the dotted line of the absorption spectrum), and the absorbed light is converted into green light that is emitted (as shown in the solid line of the emission spectrum). Therefore, if using LEDs in which the peak wavelength is shorter than 430 nm, the light conversion efficiency of the green quantum dot material can be enhanced.

However, if using LEDs in which peak wavelength is shorter than 430 nm, blue light color points of the display device would not conform to a specific color gamut standard (such as sRGB, DCI-P3, or Adobe RGB). In addition, ambient light that is incident from outside into the display device may cause the LEDs or quantum dot materials reflect or excite unnecessary light. Therefore, the contrast of the display device is decreased.

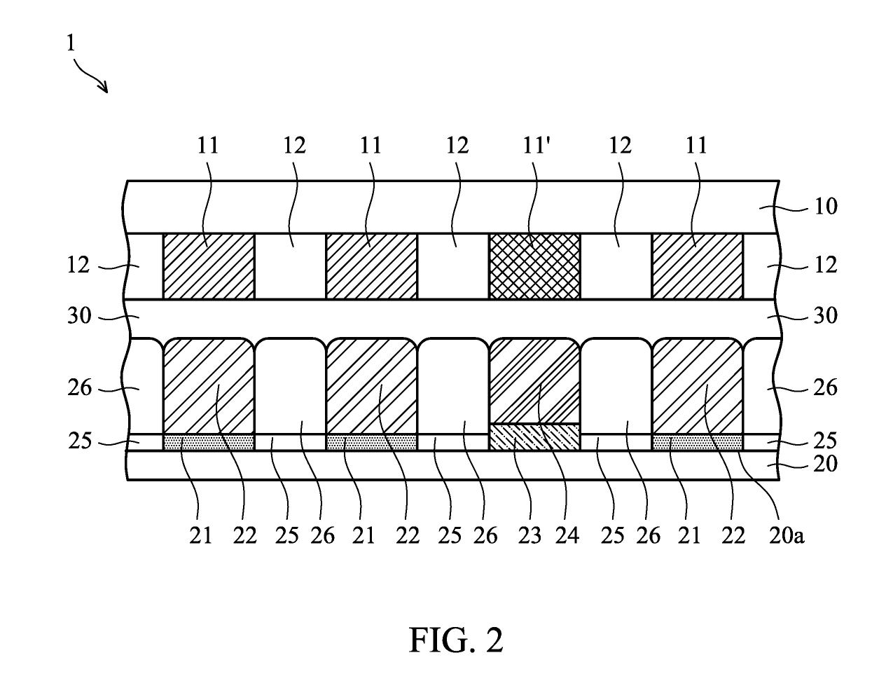

Then, referring to FIG. 2, FIG. 2 shows a cross-sectional view of a display device in accordance with an embodiment of the present disclosure. The display device 1 includes a first substrate 10, at least one first light-emitting element 11, a second light-emitting element 11′, at least one filling layer 12, a second substrate 20, at least one light filter layer 21, at least one light conversion layer 22, a color filter layer 23, a scattering layer 24, at least one shielding layer 25, at least one barrier layer 26, and a bonding layer 30.

The first substrate 10 may be a thin-film transistor array substrate, including a plurality of thin-film transistors. Driving circuits (such as gate lines, data lines, or capacitors) of the thin-film transistor array substrate, which are configured to drive the first light-emitting elements 11 and the second light-emitting element 11′, are partially omitted. The base materials of the first substrate 10 may include quartz, glass, polymethylmethacrylate (PMMA), polyimide (PI), polyethylene terephthalate (PET), polyethylene naphthalate (PEN), and polybutylene naphthalate (PBN). However, the base materials of the first substrate 10 are not limited thereto, as long as rigid (low degree of flexibility) or flexible (high degree of flexibility) materials that are suitable for the substrate are used.

Still referring to FIG. 2, the first light-emitting elements 11 and the second light-emitting element 11′ are disposed on the first substrate 10 and are electrically connected to respective thin-film transistors. The filling layer 12 is disposed between the first light-emitting elements 11 and the second light-emitting element 11′, and configured to fix each of the first light-emitting elements 11 or the second light-emitting element 11′. In addition, the filling layer 12 may also obstruct the cross-talk effect between the first light-emitting elements 11 or the second light-emitting element 11′ that are adjacent to each other. In this embodiment, the peak wavelength of the first light-emitting elements 11 is about 410 nm, and the peak wavelength of the second light-emitting element 11′ is about 450 nm, wherein the first light-emitting elements 11 and the second light-emitting element 11′ may include micro LED. However, the first light-emitting elements 11 and the second light-emitting element 11′ are not limited thereto.

The light filter layer 21 is disposed on the second substrate 20, and the transmittance of the light filter layer 21 is lower than or equal to 1% for light with a wavelength shorter than 430 nm. In this embodiment, the light filter layer 21 is disposed on one side of the second substrate 20, which is adjacent to the first substrate 10, and the light filter layer 21 patternedly corresponds to the first light-emitting elements 11. In this embodiment, the term “corresponds to” means that the light filter layer 21 and the light-emitting element 11 are at least partially overlapping in a normal direction of a surface 20a of the second substrate 20. The light filter layer 21 include a polymer material capable of absorbing short-wavelength light, or a structure that obstruct penetration of short-wavelength light using interference effect, such as a photoresist or a multi-layer film structure. However, the structure is not limited thereto. The materials of the second substrate 20 may include quartz, glass, polymethylmethacrylate (PMMA), polyimide (PI), polyethylene terephthalate (PET), polyethylene naphthalate (PEN), and polybutylene naphthalate (PBN). However, the materials of the second substrate 20 are not limited thereto, as long as rigid (low degree of flexibility) or flexible (high degree of flexibility) materials that are suitable for the second substrate 20 are used.

Still referring to FIG. 2, the light conversion layer 22 is disposed on the second substrate 20, and it corresponds to the first light-emitting elements 11. In this embodiment, the term “corresponds to” means that the light conversion layer 22 and the first light-emitting element 11 are at least partially overlapping in the normal direction of the surface 20a of the second substrate 20. In this embodiment, the light conversion layer 22 may be formed of a red quantum dot material or green quantum dot material (however, the material of the light conversion layer 22 is not limited thereto, as long as material that is capable of converting light peak wavelength from short peak wavelength into high peak wavelength can be used), which is configured to serve as red pixels or green pixels, respectively. The light filter layer 21 is disposed between the second substrate 20 and the light conversion layer 22. For example, the quantum dots may be II-VI group compounds, III-V group compounds, IV-VI group compounds, IV group compounds, group compounds, I-II-IV-VI group compounds, or combinations thereof. II-VI group compounds may be selected from the following: binary compounds selected from CdSe, CdTe, ZnS, ZnSe, ZnTe, ZnO, HgS, HgSe, HgTe, MgSe, MgS, and mixtures thereof; trinary compounds selected from CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and quaternary compounds selected from HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof. III-V group compounds may be selected from the following: binary compounds selected from GaN, GaP, GaAs, GaSb, AlN, AlP, AlAs, AlSb, InN, InP, InAs, InSb, and mixtures thereof; trinary compounds selected from GaNP, GaNAs, GaNSb, GaPAs, GaPSb, AlNP, AINAs, AlNSb, AlPAs, AlPSb, InNP, InNAs, InNSb, InPAs, InPSb, and mixtures thereof; and quaternary compounds selected from GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. IV-VI group compounds may be selected from the following: binary compounds selected from SnS, SnSe, SnTe, PbS, PbSe, PbTe, and mixtures thereof; trinary compounds selected from SnSeS, SnSeTe, SnSTe, PbSeS, PbSeTe, PbSTe, SnPbS, SnPbSe, SnPbTe, and mixtures thereof; and quaternary compounds selected from SnPbSSe, SnPbSeTe, SnPbSTe, and mixtures thereof. I-II-IV-VI group compounds may include CuZnSnSe and CuZnSnS. However, the I-II-IV-VI group compounds are not limited thereto. IV group compounds may include single element molecules selected from Si, Ge, and mixtures thereof; and binary compounds selected from SiC, SiGe, and mixtures thereof.

Accordingly, in the case that the conversion efficiency is enhanced by using the light conversion layer 22 and the first light-emitting elements 11, the display device can still conform to a specific color gamut standard by the structural design of the first light-emitting elements 11, the light filter layer 21, and the light conversion layer 22. Also, in this way, external ambient light with a short wavelength is prevented from being excited or reflected so that the contrast is decreased.

The color filter layer 23 is disposed on the second substrate 20, and the scattering layer 24 is disposed on the color filter layer 23. In this embodiment, the color filter layer 23 is a blue color filter layer that corresponds to the second light-emitting element 11′, and configured to serve as a blue pixel in the display device 1. In this embodiment, the term “corresponds to” means that the color filter layer 23 and the second light-emitting element 11′ are at least partially overlapping in the normal direction of the surface 20a of the second substrate 20. The shielding layer 25 and the barrier layer 26 are disposed on the second substrate 20, and the shielding layer 25 and the barrier layer 26 respectively correspond to the filling layer 12. In this embodiment, the term “correspond to” means that the shielding layer 25, the barrier layer 26 and the filling later 12 are at least partially overlapping in the normal direction of the surface 20a of the second substrate 20. The shielding layer 25 and the barrier layer 26 are disposed between various color pixels, and are configured to improve that lights from various color pixels mix together. In this embodiment, the shielding layer 25 and the barrier layer 26 are formed in different processes. However, it should be noted that the shielding layer 25 and the barrier layer 26 may also be formed of the same material in the same process. In some embodiments, the light filter layer 21 may be formed between the shielding layer 25 and the second substrate 20 as a whole surface without being patterned. Also, the light filter layer 21 may be formed between the shielding layer 25 and the barrier layer 26 as a whole surface without being patterned. The bonding layer 30 is disposed between the first substrate 10 and the second substrate 20. After the aforementioned elements are respectively formed on the first substrate 10 and the second substrate 20, the bonding layer 30 is configured to bond and combine the first substrate 10 and the second substrate 20. The material of the bonding layer 30 may be an optical cement. However, the material of the bonding layer 30 is not limited in the present disclosure, as long as the material used allows the light of the light-emitting element to penetrate and is capable of bonding the first substrate 10 and the second substrate 20.

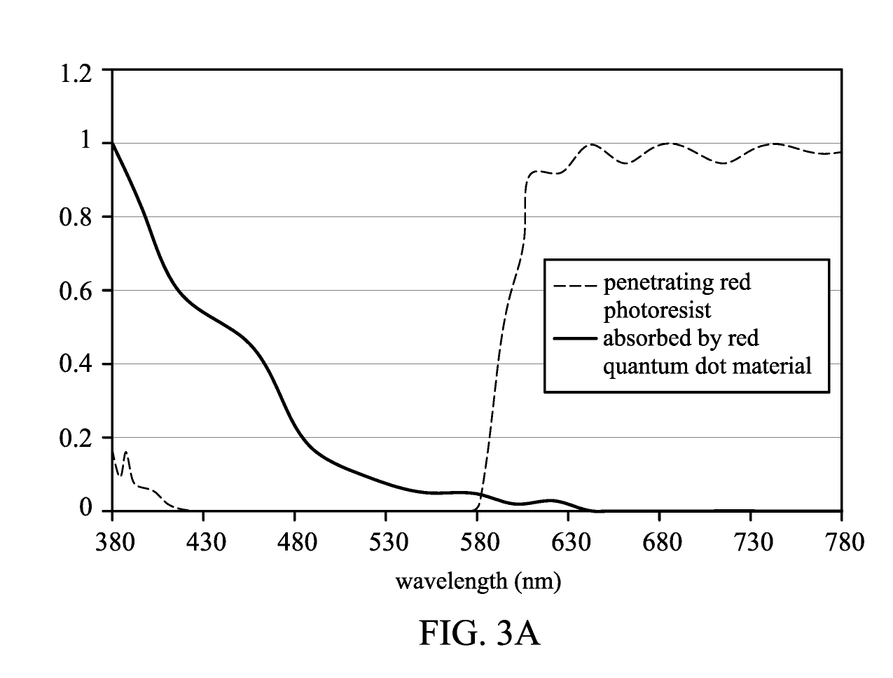

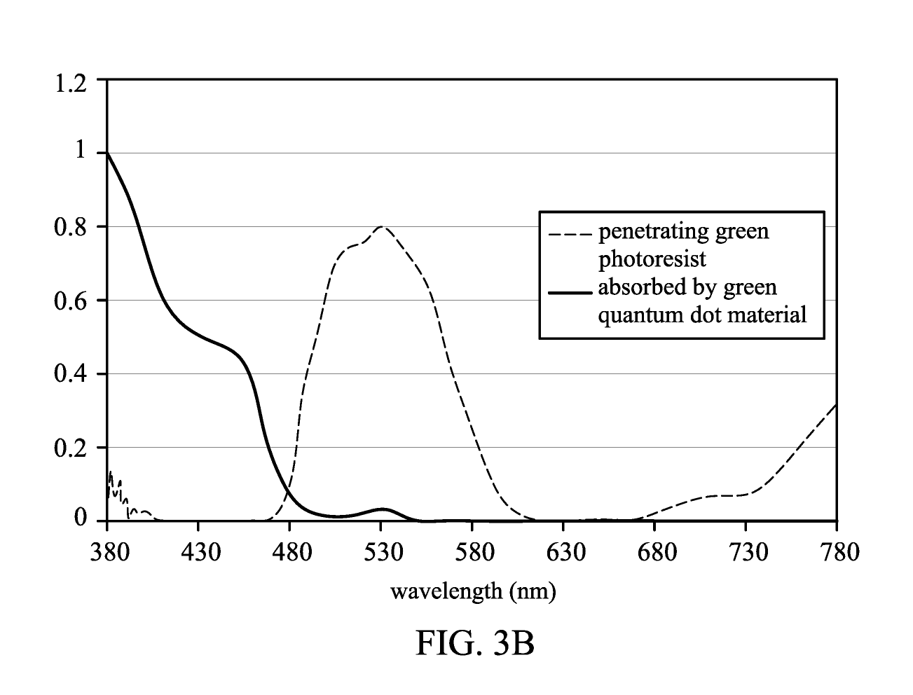

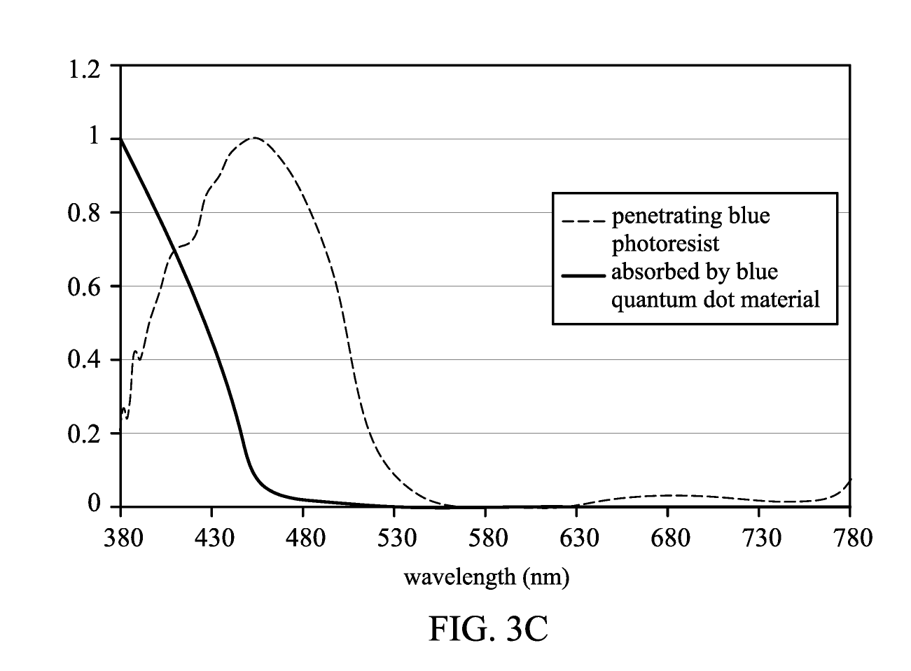

Next, referring to FIGS. 3A-3C, FIGS. 3A-3C respectively show an absorption spectrum of a red quantum dot material and a transmission spectrum of a red photoresist, an absorption spectrum of a green quantum dot material and a transmission spectrum of a green photoresist, and an absorption spectrum of a blue quantum dot material and a transmission spectrum of a blue photoresist. The horizontal axes represent wavelength, in which the unit is nanometer (nm). The vertical axes represent normalized relative intensities, therefore there is no unit.

As shown in FIG. 3A, the solid line is the absorption spectrum of the red quantum dot material, and the red quantum dot material has great absorption intensity for light with a wavelength shorter than 430 nm (as shown in the solid line of the absorption spectrum). Therefore, the conversion efficiency of the quantum dot material can be enhanced by using the first light-emitting elements 11 in which the peak wavelength is shorter than 430 nm.

Then, referring to the dotted line shown in FIG. 3A, the dotted line in FIG. 3A represents the emission spectrum of the red photoresist. FIG. 3A illustrates that the majority of light with a wavelength shorter than 580 nm is absorbed by the red photoresist so that it is difficult for light to penetrate the red photoresist. Therefore, if the red photoresist is disposed on the second substrate or on the light conversion layer, the possibility that external ambient light with a wavelength shorter than 580 nm can be absorbed by the red quantum dot material, which lowers the contrast of the display device, can be improved.

Referring to FIG. 3B, it is found that the transmittance of light with a wavelength in a range of 480 nm to 600 nm is higher than that of light with another wavelength for the green photoresist. Therefore, if the green photoresist is disposed on the second substrate or on the light conversion layer, the possibility that external ambient light with a wavelength shorter than 480 nm can be absorbed by the quantum dot material can be improved. Thus, the contrast of the display device can be enhanced.

Referring to FIG. 3C, the absorption spectrum of the blue quantum dot material and the transmission spectrum of the blue photoresist shown in FIG. 3C indicates that the blue photoresist allows light with a wavelength in a range of 380 nm to 530 nm to penetrate. Therefore, the possibility that the light source will reflect external ambient light after the external ambient light illuminates the light source can be improved. Thus, the contrast of the display device can be enhanced.

Therefore, there is a lower possibility that the quantum dot material will become excited by the external ambient light with a short wavelength, or that the light source will reflect light so that the contrast of the display device can be improved in the configuration of the light conversion layer 22 and the first light-emitting elements 11 by arranging the color filter layers (i.e. red, green, and blue photoresists).

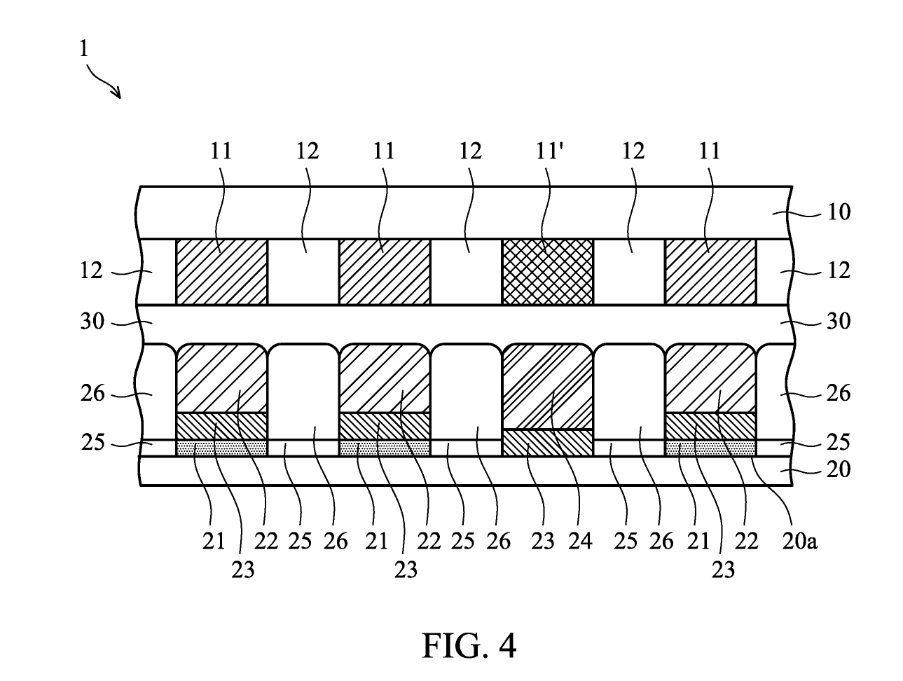

As shown in FIG. 4, FIG. 4 is a cross-sectional view of the display device in accordance with another embodiment of the present disclosure. The difference between the embodiment in FIG. 4 and the embodiment in FIG. 2 is that the display device 1 further includes a color filter layer 23, which corresponds to the first light-emitting elements 11, and the color filter layer 23 is disposed between the light filter layer 21 and the light conversion layer 22. In this embodiment, the term “corresponds to” means that the color filter layer 23 and the first light-emitting elements 11 are at least partially overlapping in the normal direction of the surface 20a of the second substrate 20. In this embodiment, the light conversion layer 22 may be formed of red quantum dot material or green quantum dot material, and the color filter layer 23 may be formed of a red photoresist or a green photoresist, which are respectively configured to serve as a red pixel or a green pixel. However, those materials are not limited thereto in the present disclosure.

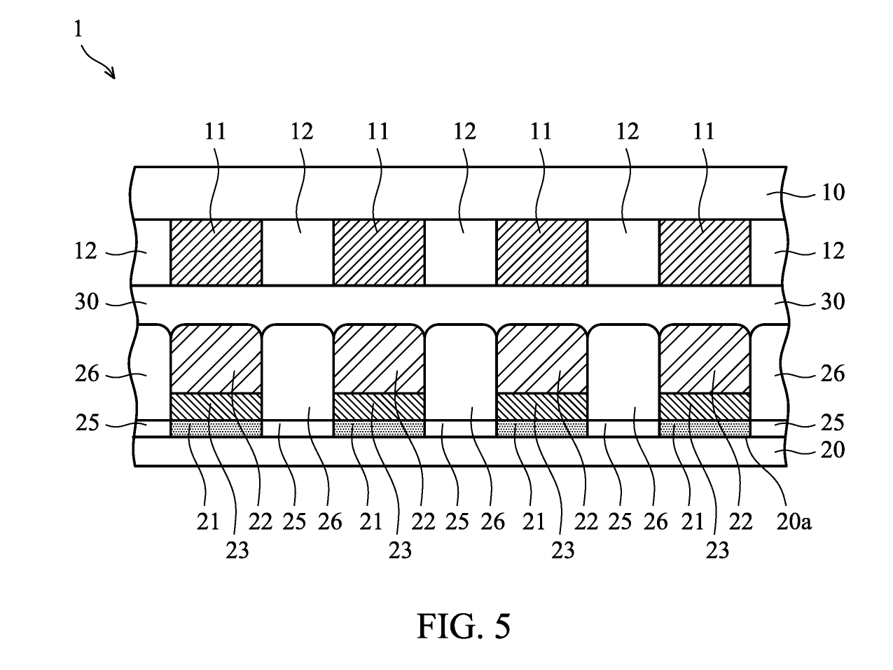

Next, referring to FIG. 5, FIG. 5 is a cross-sectional view of the display device in accordance with another embodiment of the present disclosure. The difference between the embodiment in FIG. 5 and the embodiment in FIG. 2 is that the peak wavelength of all the first light-emitting elements 11 disposed on the first substrate 10 is about 410 nm. The light conversion layer 22 and the color filter layer 23 respectively correspond to the first light-emitting elements 11, and the color filter layer 23 is disposed between the light filter layer 21 and the light conversion layer 22. In this embodiment, the term “correspond to” means that the light conversion layer 22, the color filter layer 23 and the first light-emitting element 11 are at least partially overlapping in the normal direction of the surface 20a of the second substrate 20. In this embodiment, the light conversion layer 22 may be formed of red quantum dot material, green quantum dot material, or blue quantum dot material, and the color filter layer 23 may be formed of a red photoresist, a green photoresist, or a blue photoresist, which is configured to serve as a red pixel, a green pixel, or a blue pixel, respectively. In some embodiments, the first light-emitting elements 11 may be red LEDs, green LEDs, or blue LEDs.

Therefore, conversion efficiency is enhanced in the configuration of the light conversion layer 22 and the first light-emitting elements 11, but the display device still conforms to the specific color gamut standard (such as sRGB, DCI-P3, or Adobe RGB) by arranging the color filter layers (i.e. red, green, and blue photoresists) as indicated in the embodiments shown in FIGS. 4 and 5. Also, the possibility that the quantum dot material will be excited by external ambient light with a short wavelength can be improved. The possibility that the light source will reflect light, which causes the display device to have a lower contrast, can also be improved.

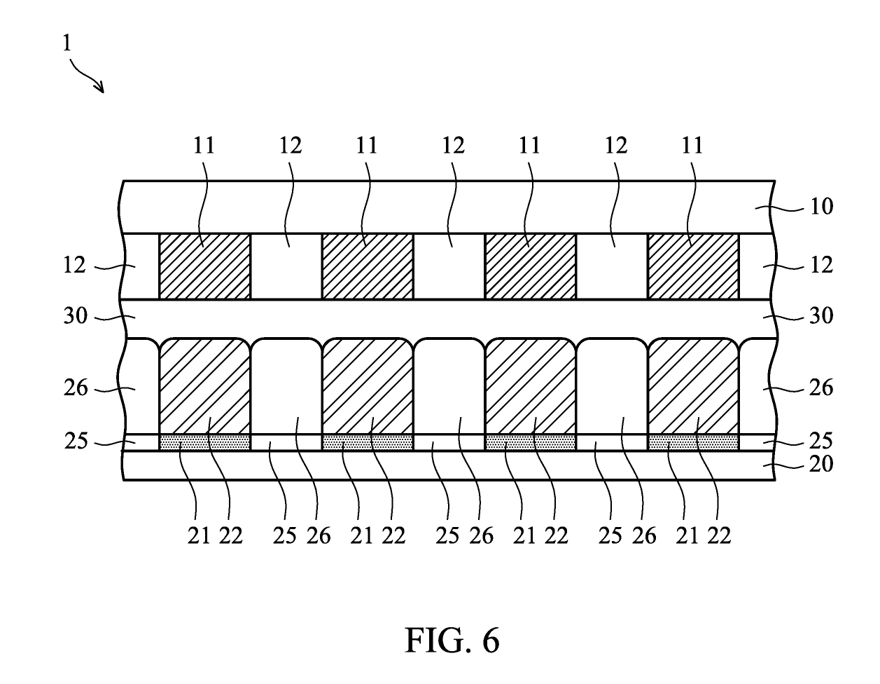

Referring to FIG. 6, FIG. 6 is a cross-sectional view of the display device in accordance with another embodiment of the present disclosure. The difference between the embodiment in FIG. 6 and the embodiment in FIG. 5 is that the one in FIG. 6 has no color filter layer disposed between the light filter layer 21 and the light conversion layer 22. That is, the light filter layer 21 and the light conversion layer 22 are in contact with each other. It should be noted that when external quantum efficiency (EQE) of the red quantum dot material, the green quantum dot material, or the blue quantum dot material (the light conversion layer 22) reaches a certain degree, a good conversion can be performed to the light emitted by the first light-emitting elements 11, in which the peak wavelength is about 410 nm. Thus, a color filter layer is not required.

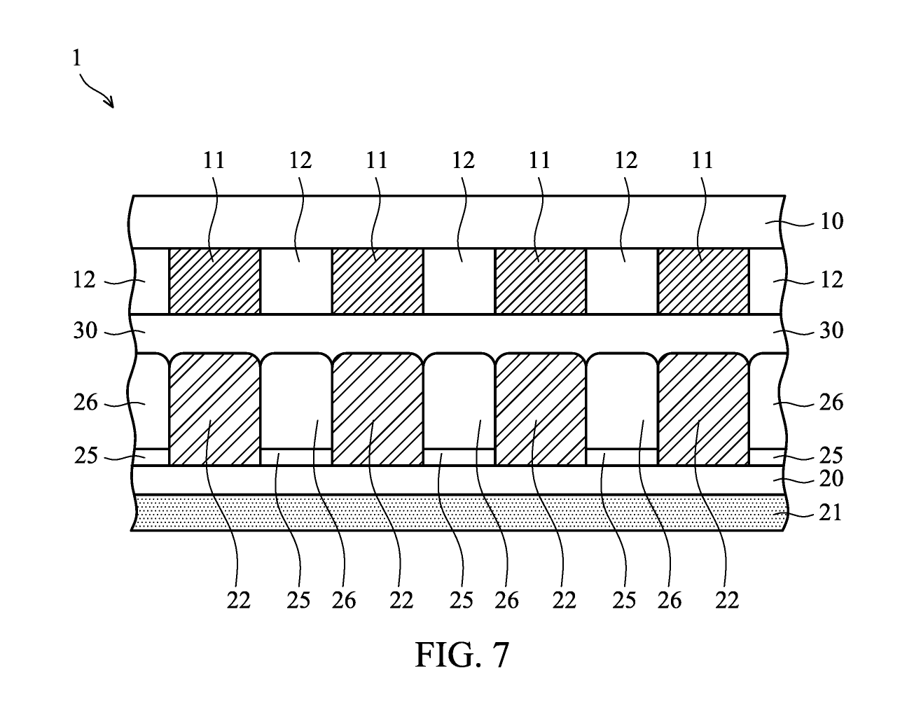

Referring to FIG. 7, FIG. 7 is a cross-sectional view of the display device in accordance with another embodiment of the present disclosure. The difference between the embodiment in FIG. 7 and the embodiment in FIG. 6 is that the one in FIG. 7 has a light filter layer 21 disposed on the side of the second substrate 20 that is away from the first substrate 10. In some embodiments, the color filter layer 21 may be combined into an optical clear adhesive (OCA) or an optical clear resin (OCR) configured to paste touch panels, or it may be combined into an insulating layer of the touch panel. In addition, the color filter layer 21 may be combined into an anti-static-electricity layer disposed on the surface of the display device. However, the color filter layer 21 is not limited thereto.

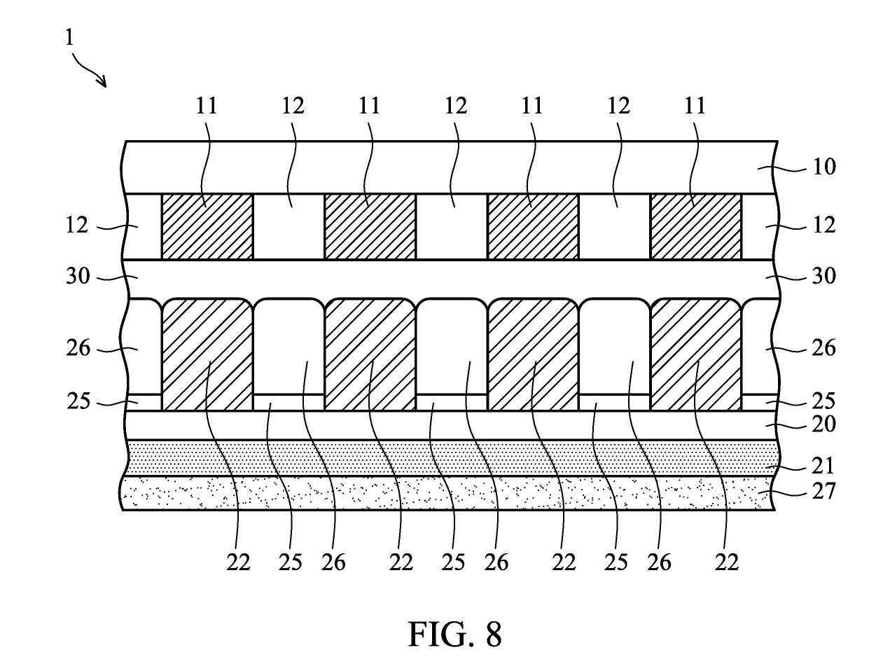

Referring to FIG. 8, FIG. 8 is a cross-sectional view of the display device in accordance with another embodiment of the present disclosure. The difference between the embodiment in FIG. 8 and the embodiment in FIG. 7 is that the one in FIG. 8 has a display device 1 that includes an anti-reflective layer 27, and a light filter layer 21 is disposed between the anti-reflective layer 27 and the second substrate 20. The anti-reflective layer 27 may include a material or a micro-structure that has a low refractive index, such as magnesium fluoride or a moth-eye structure. The arrangement of the anti-reflective layer 27 can prevent external ambient light (with a wavelength short enough to cause the contrast to drop) from entering into the display device 1.

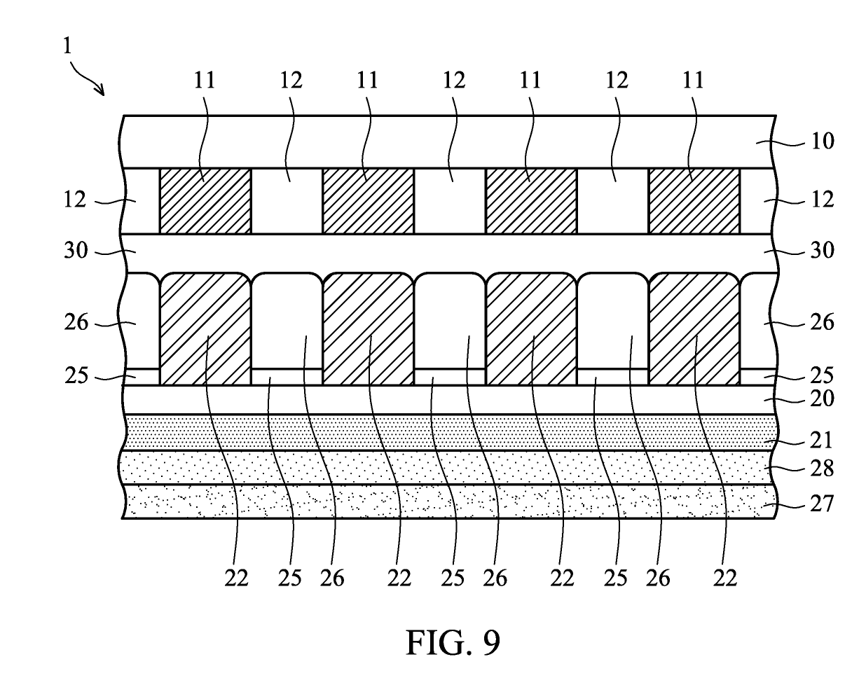

Referring to FIG. 9, FIG. 9 is a cross-sectional view of the display device in accordance with another embodiment of the present disclosure. The difference between the embodiment in FIG. 9 and the embodiment in FIG. 8 is that the one in FIG. 9 is a display device 1 that includes a circular polarizer 28 disposed between the anti-reflective layer 27 and the light filter layer 21. The arrangement of the circular polarizer 28 can block the reflective light which is the external ambient light reflected off the display device 1 after entering the display device 1. Therefore, the contrast is prevented from being decreased.

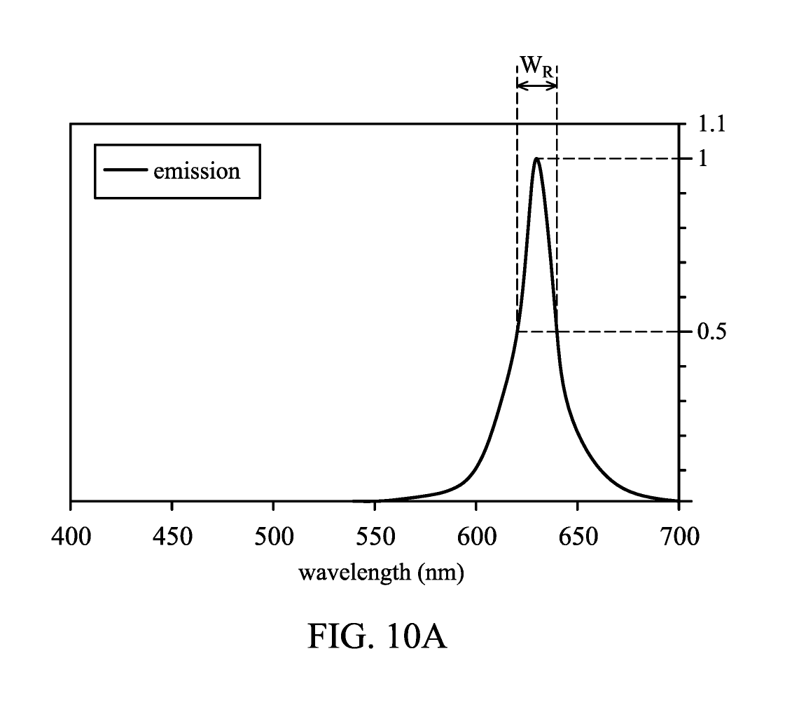

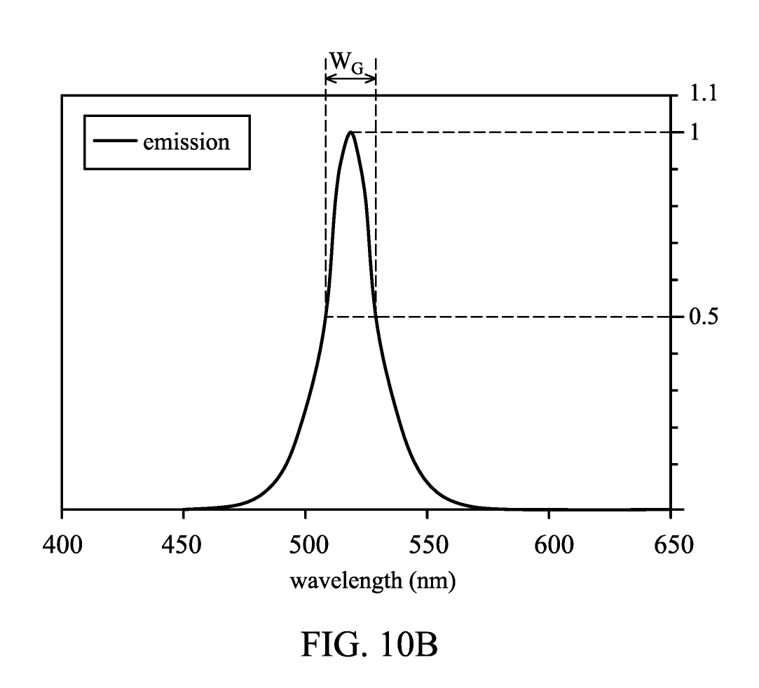

Referring to FIG. 10A, FIG. 10A is an emission spectrum of the light conversion layer 22 in accordance with an embodiment of the present disclosure. The horizontal axis represents wavelength, in which the unit is nanometer (nm). The vertical axis represents a normalized relative intensity, so there is no unit. In this embodiment, when the light conversion layer 22 is a red quantum dot material, the full width at half maximum W_{R} of the emission spectrum of the light conversion layer 22 is shorter than 20 nm, and the peak wavelength of the emission spectrum of the light conversion layer 22 is about 640 nm. In some embodiments, when the light conversion layer 22 is a red quantum dot material, and the full width at half maximum and peak wavelength of the emission spectrum conform the aforementioned conditions, red color filter layer is not required to be disposed in the display device 1.

Referring to FIG. 10B, FIG. 10B is an emission spectrum of the light conversion layer 22 in accordance with another embodiment of the present disclosure. The horizontal axis represents wavelength, in which the unit is nanometer (nm). The vertical axis represents a normalized relative intensity, so there is no unit. In this embodiment, when the light conversion layer 22 is a green quantum dot material, the full width at half maximum W_{G} of the emission spectrum of the light conversion layer 22 is shorter than 20 nm, and the peak wavelength of the emission spectrum of the light conversion layer 22 is about 530 nm. In some embodiments, when the light conversion layer 22 is a green quantum dot material, and the full width at half maximum and peak wavelength of the emission spectrum conform the aforementioned conditions, green color filter layer is not required to be disposed in the display device 1.

As set forth above, the present disclosure provides a display device with a short-wavelength light filter layer, and thereby in the case where the conversion efficiency of the quantum dot material is enhanced, the display device still conforms to the specific color gamut standard. Also, that the contrast is decreased due to the external ambient light with a short wavelength is improved.

It should be noted that the aforementioned sizes, parameters and shapes of the elements are not limitations of the present disclosure. Those skilled in the art may adjust these settings according to different needs. Moreover, the organic light-emitting diode displays and the methods for manufacturing the same of the present disclosure are not limited to the configurations shown in FIGS. 1-10B. Some embodiments of the present disclosure may include any one or more features of any one or more embodiments of FIGS. 1-10B. That is to say, not every feature of all the drawings should be performed at the same time in the organic light-emitting diode displays and the methods for manufacturing the same of the embodiments of the present disclosure.

While the present disclosure has been described by way of example and in terms of some embodiments, it is to be understood that those skilled in the art may make various changes, substitutions, and alterations to the present disclosure without departing from the spirit and scope of the present disclosure. For example, different features in different embodiments can mix together to form another embodiment of the present disclosure. In addition, the scope of the present disclosure is not limited to the processes, machines, manufacture, composition, devices, methods and steps in the specific embodiments described in the specification. From some embodiments of the present disclosure, those skilled in the art may understand existing or developing processes, machines, manufacture, compositions, devices, methods and steps, which may be performed in the aforementioned embodiments or obtained substantially the same result, may be used in accordance with some embodiments of the present disclosure. Therefore, the scope of the present disclosure includes the aforementioned processes, machines, manufacture, composition, devices, methods, and steps. Furthermore, each of the appended claims constructs an individual embodiment, and the scope of the present disclosure also includes every combination of the appended claims and embodiments.

What is claimed is:

1. A display device, comprising:
a first substrate;
a first light-emitting element disposed on the first substrate;
a second substrate disposed opposite to the first substrate;
a light conversion layer disposed on the second substrate, and corresponding to the first light-emitting element; and
a light filter layer disposed on the second substrate, wherein the transmittance of the light filter layer is lower than or equal to 1% for light with a wavelength shorter than 430 nm.

2. The display device as claimed in claim 1, wherein the light filter layer is disposed on one side of the second substrate which is adjacent to the first substrate.

3. The display device as claimed in claim 2, further comprising an anti-reflective layer and a circular polarizer, wherein the circular polarizer is disposed between the anti-reflective layer and the light filter layer.

4. The display device as claimed in claim 1, further comprising a color filter layer, wherein the color filter layer is disposed between the light conversion layer and the light filter layer, and the color filter layer corresponds to the first light-emitting element.

5. The display device as claimed in claim 1, wherein the light filter layer is disposed on one side of the second substrate which is away from the first substrate.

6. The display device as claimed in claim 5, further comprising an anti-reflective layer, wherein the light filter layer is disposed between the anti-reflective layer and the second substrate.

7. The display device as claimed in claim 6, wherein the anti-reflective layer comprises a material or a micro-structure that has a low refractive index.

8. The display device as claimed in claim 1, wherein a peak wavelength of the first light-emitting element is about 410 nm.

9. The display device as claimed in claim 8, further comprising a second light-emitting element disposed on the first substrate, wherein a peak wavelength of the second light-emitting element is about 450 nm.

10. The display device as claimed in claim 9, further comprising a filling layer disposed between the first light-emitting element and the second light-emitting element.

11. The display device as claimed in claim 10, further comprising a shielding layer disposed on the second substrate, wherein the shielding layer corresponds to the filling layer.

12. The display device as claimed in claim 11, wherein the light filter layer is disposed between the shielding layer and the second substrate.

13. The display device as claimed in claim 11, further comprising a barrier layer disposed on the second substrate, wherein the barrier layer corresponds to the filling layer.

14. The display device as claimed in claim 13, wherein the light filter layer is disposed between the shielding layer and the barrier layer.

15. The display device as claimed in claim 1, wherein the full width at half maximum of an emission spectrum of the light conversion layer is shorter than 20 nm, and the peak wavelength of the emission spectrum of the light conversion layer is about 640 nm.

16. The display device as claimed in claim 15, wherein the light conversion layer comprises a red quantum dot material.

17. The display device as claimed in claim 1, wherein the full width at half maximum of an emission spectrum of the light conversion layer is shorter than 20 nm, and the peak wavelength of the emission spectrum of the light conversion layer is about 530 nm.

18. The display device as claimed in claim 17, wherein the light conversion layer comprises a green quantum dot material.

19. The display device as claimed in claim 1, wherein the light conversion layer is in contact with the light filter layer.

20. The display device as claimed in claim 1, further comprising a bonding layer disposed between the first substrate and the second substrate.
